(19) United States
(12) Patent Application Publication
(10) Pub. No.: US 2016/0013406 A1
(43) Pub. Date: Jan. 14, 2016

(54) VARIABLE RESISTIVE MEMORY DEVICE

(71) Applicants: JIN-WOO LEE, HWASEONG-SI (KR); YOUN-SEON KANG, YONGIN-SI (KR)

(72) Inventors: JIN-WOO LEE, HWASEONG-SI (KR); YOUN-SEON KANG, YONGIN-SI (KR)

(21) Appl. No.: 14/791,619

(22) Filed: Jul. 6, 2015

(30) Foreign Application Priority Data
Jul. 8, 2014 (KR) 10-2014-0085354

(51) Int. Cl. H01L 45/00

(52) U.S. Cl. CPC H01L 45/146; H01L 45/1253

(57) ABSTRACT

A variable resistance memory device includes a first electrode layer, a variable resistance layer disposed on the first electrode layer, a second electrode layer disposed on the variable resistance layer, a barrier layer disposed between the variable resistance layer and one of the first and second electrode layers, and a buffer layer disposed between the barrier layer and one of the first and second electrode layers.

### PRIORITY STATEMENT

This application claims the benefit of Korean Patent Application No. 10-2014-0085354, filed on Jul. 8, 2014, in the Korean Intellectual Property Office, the disclosure of which is hereby incorporated by reference in its entirety.

### BACKGROUND

The inventive concept relates to a memory device and more particularly, to a variable resistive memory device.

Variable resistance memory devices are replacing flash memory devices in many of today's electronic products. A variable resistive memory device uses a resistance layer whose ability to transmit current can be changed by, for example, impressing a certain voltage across the layer. Examples of a variable resistive memory device include a phase-change random access memory (PRAM), magnetic RAM (MRAM), ferroelectric RAM (FeRAM), resistance RAM (RRAM), and polymer RAM.

### SUMMARY

According to one aspect of the inventive concept, there is provided a variable resistive memory device that includes a first electrode, a variable resistance layer disposed on the first electrode, a second electrode disposed on the variable resistance, a barrier layer disposed between the variable resistance layer and one of the first and second electrodes, and a buffer layer disposed between the barrier layer and one of the first and second electrodes.

According to another aspect of the inventive concept, there is provided a variable resistive memory device that includes a first electrode, a first barrier layer disposed on the first electrode, a variable resistance layer disposed on the first barrier layer, a second electrode disposed on the variable resistance layer, and a first reaction prevention layer disposed on the first electrode and which prevents an interaction between the first electrode and the first barrier layer.

According to another aspect of the inventive concept, there is provided a variable resistance memory device that includes a first electrode, a first buffer layer disposed on the first electrode, a first barrier layer disposed on the first buffer layer, a variable resistance layer disposed on the first barrier layer, a second barrier layer disposed on the variable resistance layer, a second buffer layer disposed on the second barrier layer, and a second electrode disposed on the second buffer layer.

According to another aspect of the inventive concept, there is provided a variable resistance memory device that includes a plurality of first signal lines that are evenly spaced apart from each other in a first direction, a plurality of second signal lines disposed on the plurality of first signal lines and evenly spaced apart from each other in a second direction that is perpendicular to the first direction, and memory cells disposed at locations, respectively, where the first and second signal lines cross, and in which the memory cells are spaced apart from each other, each of the memory cells is disposed between a respective one of the first signal lines and a respective one of the second signal lines, and each of the memory cells comprises a variable resistance layer disposed on the respective first signal line, a barrier layer disposed between the variable resistance layer and one of the respective first and second signal lines, and a buffer layer disposed between the barrier layer and said one of the respective first and second signal lines.

According to another aspect of the inventive concept, there is provided a variable resistance memory device that includes a plurality of first electrode lines that are evenly spaced apart from each other in a first direction, a plurality of second electrode lines disposed on the plurality of first electrode lines and evenly spaced apart from each other in a second direction that is perpendicular to the first direction, and a plurality of pillars disposed at locations where the plurality of first and second electrode lines cross, respectively, and in which the pillars are spaced apart from each other, and each of the pillars comprises a variable resistance layer disposed on a respective one of the first signal lines, a barrier layer disposed between the variable resistance layer and one of the first and second signal lines, and a buffer layer disposed between the barrier layer and one of the first and second signal lines.

According to another aspect of the inventive concept, there is provided a variable resistance memory device that includes a memory cell array comprising a plurality of word lines that are evenly spaced apart from each other in a first direction, a plurality of bit lines disposed on the plurality of word lines and evenly spaced apart from each other in a second direction that is perpendicular to the first direction, and a plurality of memory cells connected to the plurality of word lines and bit lines, and a controller that is configured to control a recording and reading of data in and from selected ones of the memory cells, and in which each of the memory cells has a variable resistance device comprising a variable resistance layer disposed on one of the word lines, a barrier layer disposed between the variable resistance layer and one of the word and bit lines, and a buffer layer disposed between the barrier layer and one of the word and bit lines.

According to another aspect of the inventive concept, there is provided A variable resistance memory device that includes a first horizontal array of electrodes, a second horizontal array of electrodes spaced vertically from the first horizontal array, and an array of memory cells interposed between the first and second horizontal arrays of electrodes, and in which each of the memory cells is electrically connected to a respective one of the electrodes of the first horizontal array and a respective one of the electrodes of the second horizontal array, each of the memory cells has the form of a pillar interposed between the respective ones of the electrodes of the first and second horizontal arrays, and each of the pillars comprises a variable resistor an oxide layer interposed, as a barrier, between the variable resistor and the respective electrode of one of the first and second horizontal arrays, and at least one of a metal oxide layer and a metal nitride layer interposed, as a buffer, between the barrier layer and the respective electrode. The variable resistor comprises a layer of material that can assume a first state in which the resistance of the variable resistor has a first value and another state in which the resistance of the variable resistor has a second value different from the first value. The layer constituting he variable resistor, the oxide layer constituting the barrier, and each layer constituting the buffer have different compositions from one another.

### BRIEF DESCRIPTION OF THE DRAWINGS

The inventive concept will be more clearly understood from the following detailed description of exemplary embodiments made in conjunction with the accompanying drawings in which:

FIG. 1 is a perspective view of a memory cell array of a variable resistive memory device, according to the inventive concept;

FIG. 2 is a perspective view of a unit memory cell of an embodiment of a variable resistive memory device, according to the inventive concept;

FIG. 3 is a circuit diagram of a unit memory cell of an embodiment of a variable resistive memory device, according to the inventive concept;

FIG. 4 is a diagram of current and voltage properties of an embodiment of a variable resistive memory device, according to the inventive concept;

FIG. 5 is a cross-sectional view of a memory cell and a variable resistor of an embodiment of a variable resistive memory device, according to the inventive concept;

FIG. 6 is a cross-sectional view of a memory cell and a variable resistor of another embodiment of a variable resistive memory device, according to the inventive concept;

FIG. 7 is a cross-sectional view of a memory cell and a variable resistor of another embodiment of a variable resistive memory device, according to the inventive concept;

FIG. 8 is a cross-sectional view of a memory cell and a variable resistor of another embodiment of a variable resistive memory device, according to the inventive concept;

FIG. 9 is a cross-sectional view of a memory cell and a variable resistor of another embodiment of a variable resistive memory device, according to the inventive concept;

FIG. 10 is a cumulative distribution diagram showing a high resistance state and a low resistance state of an embodiment of a variable resistive memory device, according to the inventive concept;

FIG. 11 is a cumulative distribution diagram showing a high resistance state and a low resistance state of an example of a variable resistive memory device, for comparison with the results shown in FIG. 10;

FIG. 12 is a table of an interface root mean square (RMS) for an embodiment of a variable resistive memory device according to the inventive concept and a comparative example;

FIGS. 13, 14, 15, 16, 17, 18, 19 and 20 are perspective views of a variable resistive memory device during the course of its manufacture, and together illustrate an embodiment of a method of manufacturing a variable resistive memory device according to the inventive concept;

FIGS. 21 and 22 are circuit diagrams of a memory cell array of embodiments of a variable resistive memory device, according to the inventive concept;

FIG. 23 is a perspective view of an embodiment of a memory cell array according to the inventive concept;

FIG. 24 is a circuit diagram of a unit memory cell of the array of FIG. 23;

FIG. 25 is a block diagram of a variable resistive memory device according to the inventive concept;

FIG. 26 is a block diagram of a data processing system according to the inventive concept; and

FIG. 27 is a block diagram of another example of a data processing system according to the inventive concept.

### DETAILED DESCRIPTION OF THE PREFERRED EMBODIMENTS

Reference will now be made in detail to embodiments, examples of which are illustrated in the accompanying drawings.

The embodiments of the present inventive concept are provided to fully describe the present inventive concept to one of ordinary skill in the art to which the present inventive concept pertains. The embodiments may have different forms and should not be construed as being limited to the descriptions set forth herein. Instead, the embodiments more fully convey the spirit and scope of the present inventive concept to one of ordinary skill in the art. Sizes of elements in the drawings may be exaggerated or reduced for convenience of explanation. As used herein, the term “and/or” includes any and all combinations of one or more of the associated listed items. Expressions such as “at least one of,” when preceding a list of elements, modify the entire list of elements and do not modify the individual elements of the list.

Throughout the specification, it will be understood that when an element, for example, a film, a layer, an area, or a substrate, is referred to as being “on”, “connected to”, or “coupled to” another element, it can be directly “on”, “connected to”, or “coupled to” the other element, or intervening other elements may be present. On the other hand, when an element is referred to as being “directly on”, “directly connected to”, or “directly coupled to” another element, other intervening elements are not present. Like reference numerals refer to like elements.

It will be understood that although the terms “first,” “second,” etc. may be used herein to describe various members, areas, layers, portions, and/or components, these members, areas, layers, portions, and/or components should not be limited by these terms. These components do not indicate a specific order or superiority, but are only used to distinguish one member, area, layer, portion or component from another. Therefore, first members, areas, portions, or components may indicate second members, areas, portions, or components without departing from teachings of the present inventive concept.

Also, relative terms, such as “upper” or “on” and “lower” or “under,” may be used to describe a relationship between a component and another component as illustrated in the accompanying drawings. The relative terms may be understood as including directions of a device other than directions illustrated in the accompanying drawings. For example, if a device is turned over in a drawing, a component described as being on an upper surface of another component is shown as being on a lower surface of the other component. Therefore, the exemplary term “on” may include directions indicated by the terms “under” and “on” based on a certain direction in a drawing. If the device faces another direction (rotates by 90° to the other direction), the descriptions in the present specification may be understood accordingly.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

The term “extending” as used in connection with describing the geometry of an element or feature will generally be understood to refer to the longest dimension of the element or feature, e.g., the lengthwise direction of a line-shaped element or feature, as the context and drawings will make clear. The term “connected” may refer to an electrical connection even if not explicitly stated, i.e., again, as the context will make clear. The term “electrode” is generally used in its broadest sense as referring to a conductor or section of a conductor whose main purpose is to transmit current to or from a particular component. The term “layer” may refer to a layer in its original form or after having had a portion or portions thereof removed by, for example, an etching process. The term “pattern” may refer to a series of elements or features formed by a patterning process, such as an etching process, or may simply refer to one such element or feature formed by a patterning process as the context will make clear.

Reference will now be made in detail to embodiments, examples of which are schematically illustrated in the accompanying drawings. In the accompanying drawings, the present embodiments may have different forms according to, for example, a manufacturing technology and/or tolerance. Therefore, the embodiments of the present inventive concept should not be construed as being limited to the descriptions set forth herein, but should include, for example modifications created during a manufacturing process. Any one of the embodiments of the present inventive concept or a combination thereof may be implemented.

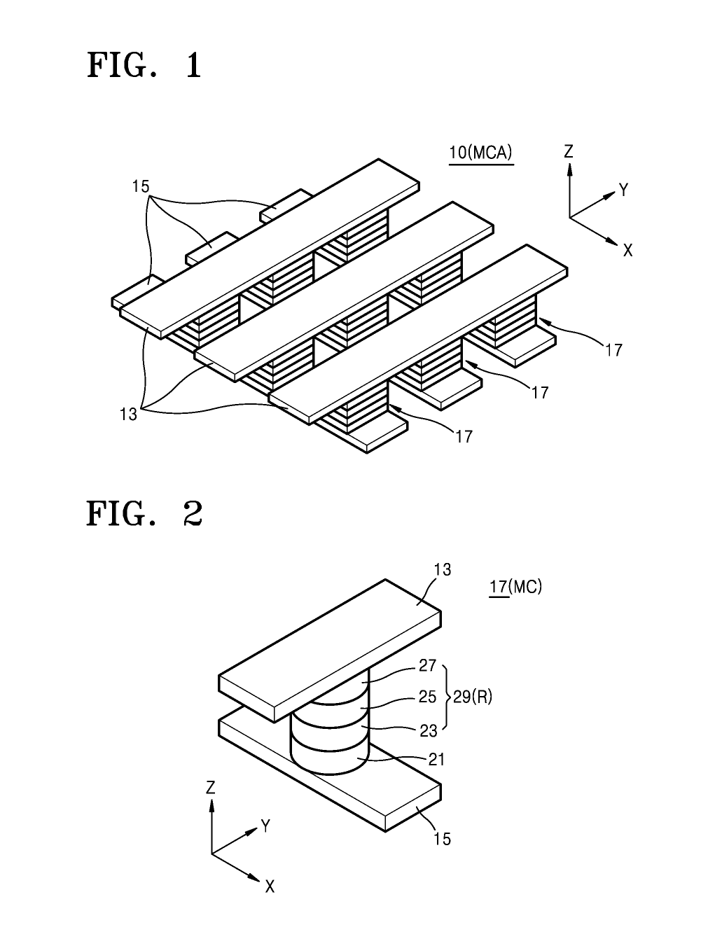

FIG. 1 is a perspective view of a memory cell array MCA 10 of an embodiment of a variable resistive memory device, according to the inventive concept.

The memory cell array MCA 10 includes a plurality of memory cells 17, a plurality of first signal lines 15 and a plurality of second signal lines 13. The first signal lines 15 and the second signal lines 13 are substantially perpendicular to each other, and the memory cells 17 are provided at locations where the first and second signal lines 15 and 13 cross.

The first signal lines 15 may be first conductive lines. The second signal lines 13 may be second conductive lines. The first signal lines 15 each extend in an X-axis direction and may be spaced apart in a Y-axis direction. The second signal lines 13 are spaced apart from the first signal lines 15 in a Z-axis direction. The second signal lines 13 each extend in the Y-axis direction and are spaced apart in the X-axis direction.

The first and second signal lines 15 and 13 may be arrayed as desired. For example, if the first signal lines 15 are arrayed in a row direction, the second signal lines 13 may be arrayed in a column direction. If the first signal lines 15 are serve as word lines, the second signal lines 13 may serve as bit lines.

The memory cells 17 are formed of at least one layer of material. And although FIG. 1 illustrates an example in which each of the memory cells 17 comprises vertically stacked elements, alternatively, the memory cells 17 may comprise a horizontal structure. In any case, the memory cells 17 store digital information in the form of their resistance, which may take on different values depending on a state of the cell 17. For example, each of the cells 17 may selectively assume a high resistance state and a low resistance state.

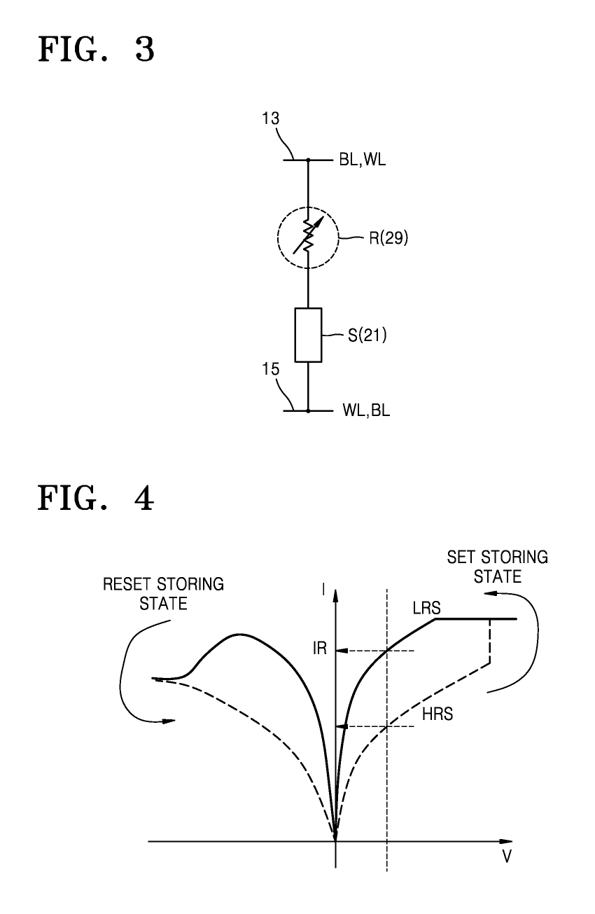

FIG. 2 is a perspective view of an example of the memory cells of the variable resistive memory device.

A memory cell MC 17 may include a selection device (pattern) 21 and a pillar 29 between respective ones of the first and second signal lines 15 and 13. The selection device (pattern) 21 may be omitted in certain applications in which such a selection device is unnecessary.

The pillar 29 may have a first pattern 23, a second pattern 25, and a third pattern 27 stacked one on the other. Although the pillar 29 of the memory cell 17 of FIG. 2 is shown as having three patterns, the pillar is not limited to having only three patterns. In any case, the pillar 29 comprises a variable resistor R.

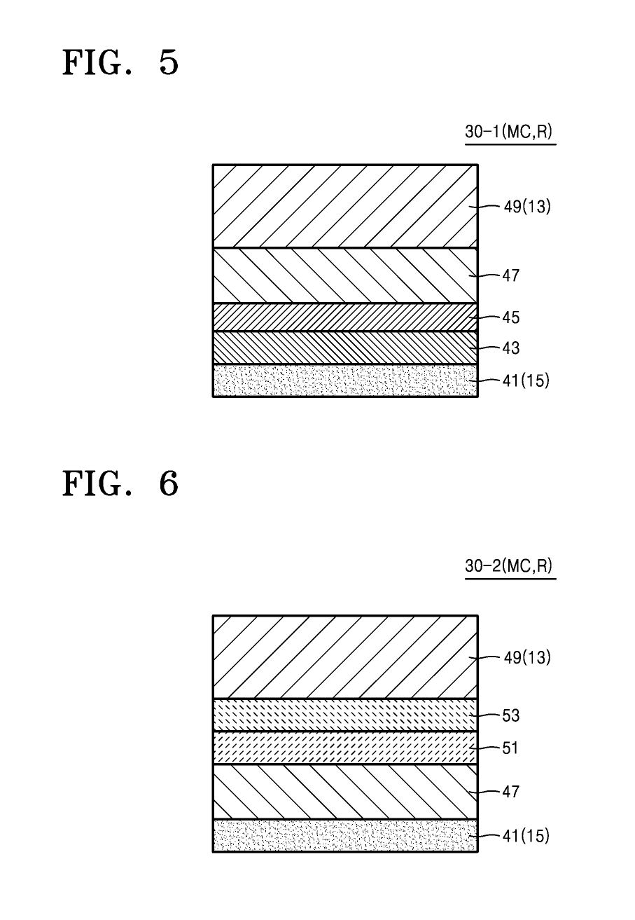

FIG. 3 is a circuit diagram of the memory cell of the variable resistive memory device.

The memory cell may include a variable resistor R and a selection device S between a bit line BL and a word line WL. As mentioned above, the selection device S may be omitted if it is unnecessary.

In the case in which a selection device is used, the selection device S may be a current adjustment device that controls current flow. For example, the selection device S may be a one-way diode, a two-way diode, or a transistor. The selection device S may be formed of a silicon-based material, a transition metal oxide, or chalcogenide glass. The selection device S may be a metal/silicon/metal (MSM) selection device. The selection device S may be a silicon diode, an oxide diode, or a tunneling diode.

The variable resistor R may be formed of a phase-change material (Ge—Sb—Te (GST)) whose resistance changes according to temperature. In this case, the variable resistive memory device may be a phase-change random access memory (PRAM). As another example, the variable resistor R is formed of an upper electrode, a lower electrode, and a transition metal oxide therebetween, such that the variable resistive memory device may be a resistance RAM (RRAM). As another example, the variable resistor R is formed of a magnetic upper electrode of a magnetic material, a lower electrode of a magnetic material, and a dielectric material therebetween, such that the variable resistive memory device may be a magnetic RAM (MRAM).

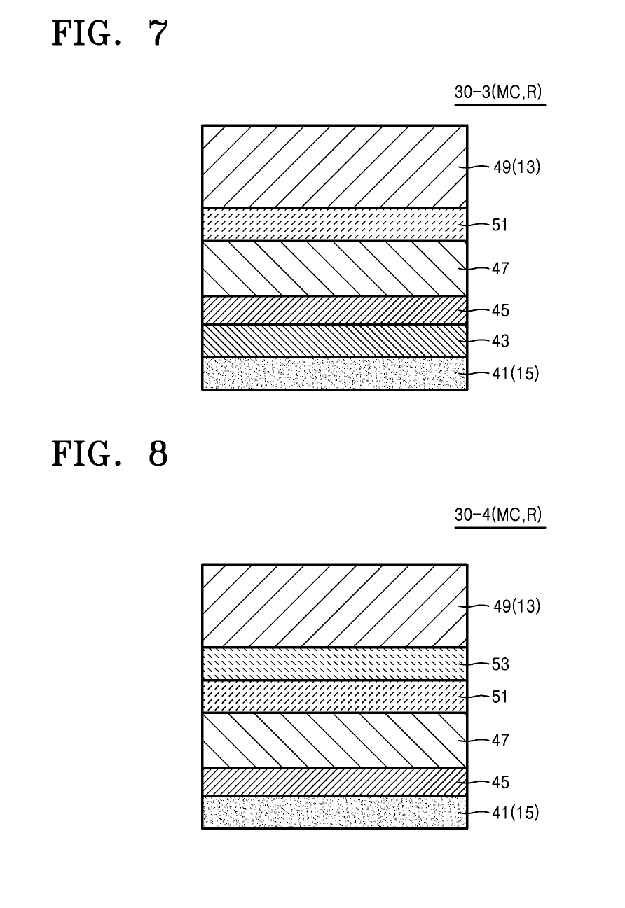

FIG. 4 is a diagram of current and voltage properties of the variable resistive memory device.

As a voltage increases, the variable resistive memory device is in a SET storing state in which the variable resistive memory device may be switched from a high resistance state HRS to a low resistance state LRS. As the voltage decreases, the variable resistive memory device is in a RESET storing state in which the variable resistive memory device may be switched from the low resistance state LRS to the high resistance state HRS.

Whether the variable resistive memory device is in the low resistance state LRS or the high resistance state HRS may be determined by detecting a read current IR at a predetermined voltage. Accordingly, the variable resistive memory device may provide on-off digital information through its ability to selectively assume the low resistance state LRS and the high resistance state HRS.

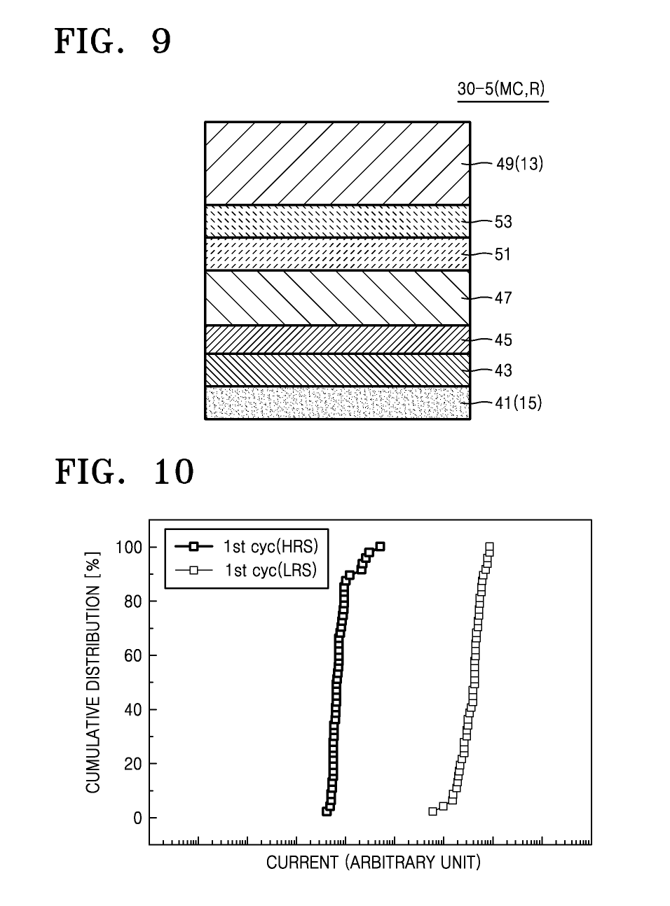

FIG. 5 is a cross-sectional view of an embodiment of a variable resistive memory device, according to the inventive concept, comprising a memory cell MC having a variable resistor R (which device will be referred to hereinafter as an MC/R 30-1).

The MC/R (30-1) may have a stacked pattern or a pillar of material layer patterns. The MC/R (30-1) may include a first electrode layer 41, a first buffer layer 43 formed on the first electrode layer 41, a first barrier layer 45 formed on the first buffer layer 43, a variable resistance layer 47 formed on the first barrier layer 45, and a second electrode layer 49 formed on the variable resistance layer 47.

The first electrode layer 41 may be a word line 15 of the MC/R, that is, a first electrode line. The second electrode layer 49 may be a bit line 13, that is, a second electrode line. In the MC/R (30-1), adjacent layers are not formed of the same material.

The first buffer layer 43 may be a first reaction prevention layer that prevents an interaction between the first electrode layer 41 and the first barrier layer 45. The first buffer layer 43 may be a first interface improvement layer or a first interface planarization layer that improves the interface morphology between the first electrode layer 41 and the first barrier layer 45. The first buffer layer 43 may be a first front surface improvement layer that improves the front surface morphology of the first electrode layer 41. Accordingly, the first buffer layer 43 may perform various functions.

The first and second electrode layers 41 and 49 may be metal layers, metal oxide layers, or metal nitride layers. For example, the first and second electrode layers 41 and 49 may be formed of at least one material selected from aluminum (Al), copper (Cu), titanium nitride (TiN), titanium aluminum nitride (TixAlyNz), iridium (Ir), platinum (Pt), silver (Ag), gold (Au), ruthenium (Ru), polysilicon, tungsten (W), titanium (Ti), tantalum (Ta), tantalum nitride (TaN), tungsten nitride (WN), nickel (Ni), cobalt (Co), chrome (Cr), antimony (Sb), iron (Fe), molybdenum (Mo), palladium (Pd), tin (Sn), zirconium (Zr), zinc (Zn), rhodium (Rh), hafnium (Hf), iridium oxide (IrO₂), indium oxide (ITO), and strontium zirconium oxide (StZrO₃).

The first buffer layer 43 may be a metal oxide layer, a metal nitride layer, or a combination thereof. For example, the first buffer layer 43 may be formed of at least one material selected from the group consisting of TiCN, TiAlN, TiSiN, TaN, TaCN, TaSiN, TaA1N, TaZrO, TiSi, TiRuO₃, HfN, ZrN, WN, AlN, and RuTiN.

In an example of this embodiment, the first barrier layer 45 is an oxide layer. For example, the first barrier layer 45 may be formed of at least one material selected from the group consisting of SiO₂, NiO, TiO, WO, TaO, AlO, ZrO, HfO, CuO, CoO, FeO, VO, YO, MoO, LaO, NbO, SrTiO, and MgO. The first barrier layer 45 may chemically and physically insulate the variable resistance layer 47 from the first electrode layer 41.

The variable resistance layer 47 may be of material layer whose resistance changes when it experience changes in an electric field. The variable resistance layer 47 may include a metal oxide layer. The variable resistance layer 47 comprises a material different from that of the first barrier layer 45. For example, the variable resistance layer 47 may be formed by of at least one material selected from the group consisting of NiO, TiO, WO, TaO, AlO, ZrO, HfO, CuO, CoO, FeO, VO, YO, MoO, LaO, NbO, SrTiO, and MgO. The variable resistance layer 47 may include an oxide having a perovskite structure, for example, PrCaMnO, LaCaMnO, or Sr(Zr)TiO₃. The variable resistance layer 47 may include solid electrolytes that include metal ions that diffuse relatively well (e.g., Cu or Ag ions). For example, the variable resistance layer 47 may comprise GeSe, GeTe, GeS, Cu₂S, or AgGeSe.

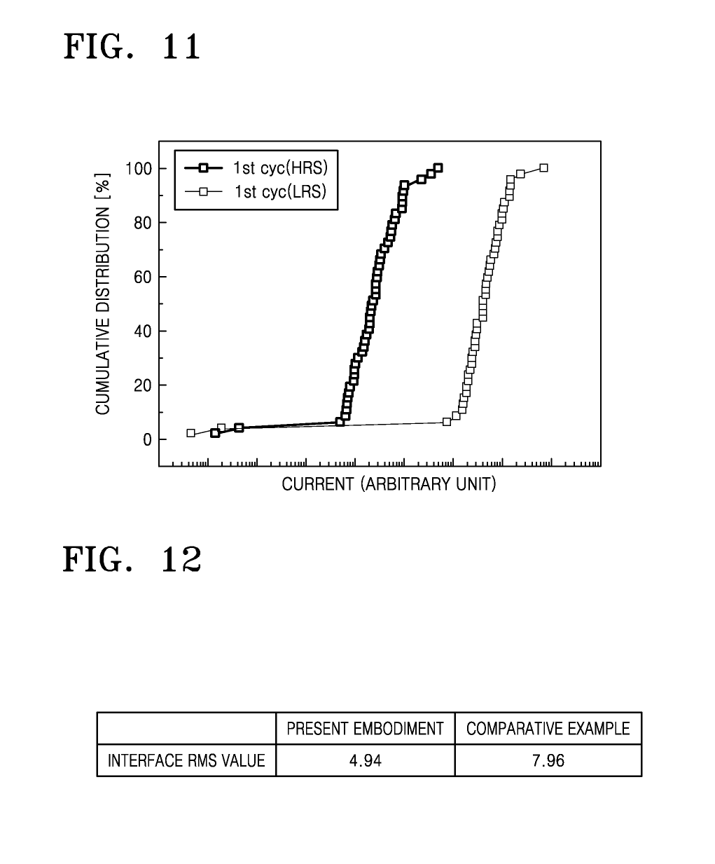

FIG. 6 is a cross-sectional view of another embodiment of a variable resistive memory device MC/R (30-2), according to the inventive concept.

Compared to the embodiment of FIG. 5, the MC/R (30-2) does not include the first barrier layer 45 and the first buffer layer 43 under the variable resistance layer 47, but includes a second barrier layer 51 and a second buffer layer 53 on the variable resistance layer 47. Otherwise, the embodiments of FIGS. 5 and 6 are the same.

Thus, the MC/R (30-2) includes first electrode layer 41, variable resistance layer 47 formed on the first electrode layer 41, the second barrier layer 51 formed on the variable resistance layer 47, the second buffer layer 53 formed on the second barrier layer 51, and second electrode layer 49 formed on the second buffer layer 53. In the MC/R (30-2), adjacent layers are not formed of the same material.

The second buffer layer 53 may be a second reaction prevention layer that prevents an interaction between the second electrode layer 49 and the second barrier layer 51. The second buffer layer 53 may be a second interface improvement layer or a second interface planarization layer that improves the interface morphology between the second electrode layer 49 and the second barrier layer 51. The second buffer layer 53 may be a back surface improvement layer that improves the back surface morphology of the second electrode layer 49. The second barrier layer 51 and the second buffer layer 53 may be respectively formed of the same material as the first barrier layer 45 and the first buffer layer 43 of the embodiment of FIG. 5.

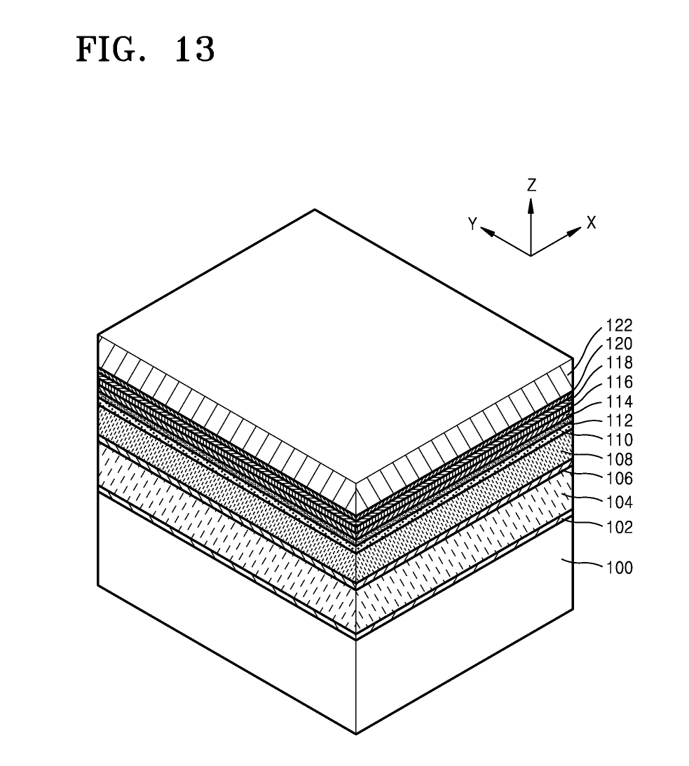

FIG. 7 is a cross-sectional view of another embodiment of a variable resistive memory device MC/R(30-3), according to the inventive concept.

The MC/R (30-3) is a combination of the embodiments of FIGS. 5 and 6. The MC/R (30-3) thus includes first electrode layer 41, first buffer layer 43 formed on the first electrode layer 41, first barrier layer 45 formed on the first buffer layer 43, variable resistance layer 47 formed on the first barrier layer 45, second barrier layer 51 formed on the variable resistance layer 47, and second electrode layer 49 formed on the second barrier layer 51.

In the MC/R (30-3), adjacent layers are not formed of the same material. The functions of the first buffer layer 43 will not be described again; instead, reference may be made to the description of the first buffer layer of the embodiment of FIG. 5.

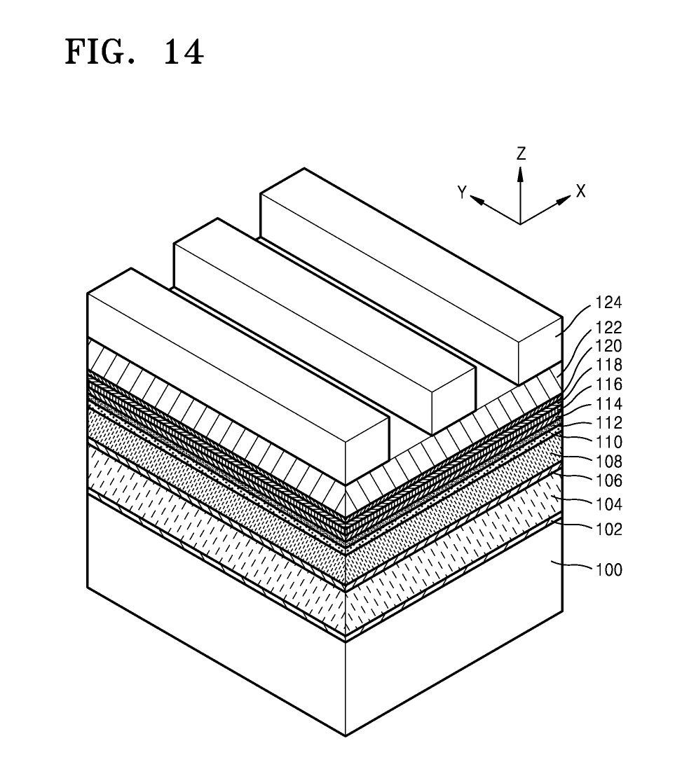

FIG. 8 is a cross-sectional view of another embodiment of a variable resistive memory device MC/R (30-4), according to the inventive concept

Compared to the embodiment of FIG. 6, the MC/R (30-4) includes first barrier layer 45 under the variable resistance layer 47. Otherwise, the embodiments of FIGS. 6 and 8 are the same.

Thus, the MC/R (30-4) includes first electrode layer 41, first barrier layer 45 formed on the first electrode layer 41, variable resistance layer 47 formed on the first barrier layer 45, second barrier layer 51 formed on the variable resistance layer 47, second buffer layer 53 formed on the second barrier layer 51, and second electrode layer 49 formed on the second buffer layer 53.

In the MC/R (30-4), adjacent layers are not formed of the same material. The functions of the first barrier layer 45, the second barrier layer 51, and the second buffer layer 53 have been described with reference to FIGS. 5 to 7 and thus, will not be described here again.

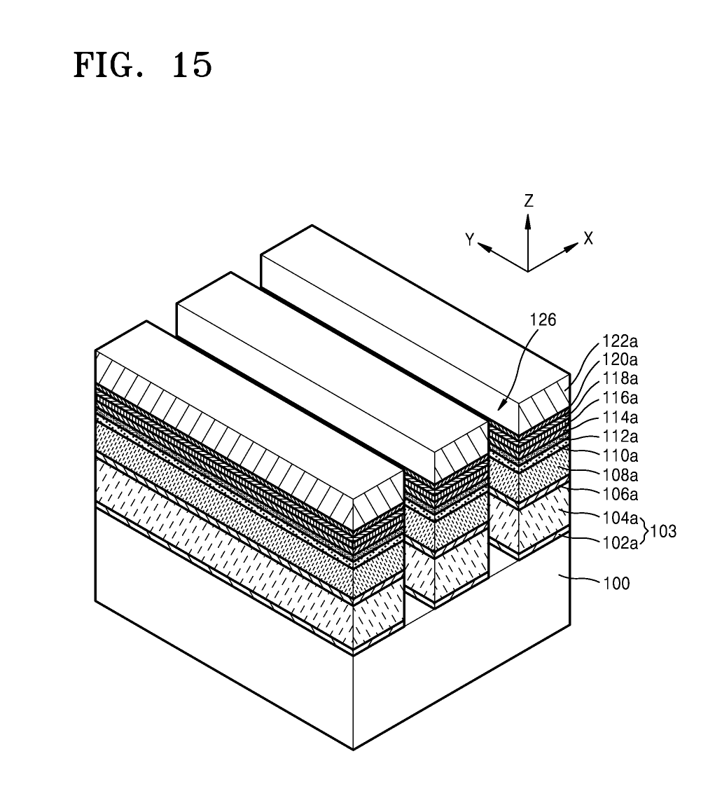

FIG. 9 is a cross-sectional view of another embodiment of a variable resistive memory device MC/R (30-5), according to the inventive concept.

In comparison to the embodiment of FIG. 7, the MC/R (30-5) includes second buffer layer 53 formed on the second barrier layer 51. Otherwise, the embodiments of FIGS. 7 and 9 are the same.

Thus, the MC/R (30-5) includes first electrode layer 41, first buffer layer 43 formed on the first electrode layer 41, first barrier layer 45 formed on the first buffer layer 43, variable resistance layer 47 formed on the first barrier layer 45, second barrier layer 51 formed on the variable resistance layer 47, second buffer layer 53 formed on the second barrier layer 51, and second electrode layer 49 formed on the second buffer layer 53.

In the MC/R (30-5), adjacent layers are not formed of the same material. Also, the functions of the first and second buffer layers 43 and 53 have been described with reference to FIGS. 5 to 8 and thus, will not be described here again.

Embodiments of a variable resistive memory device, according to the inventive concept, as described with reference to FIGS. 5 to 8, include a barrier layer (45 and 51) disposed between the variable resistance layer 47 and at least one of the first electrode layer 41 and the second electrode layer 49, and a buffer layer (43 and 53) disposed between the barrier layer (45 and 51) and at least one of the first electrode layer 41 and the second electrode layer 49.

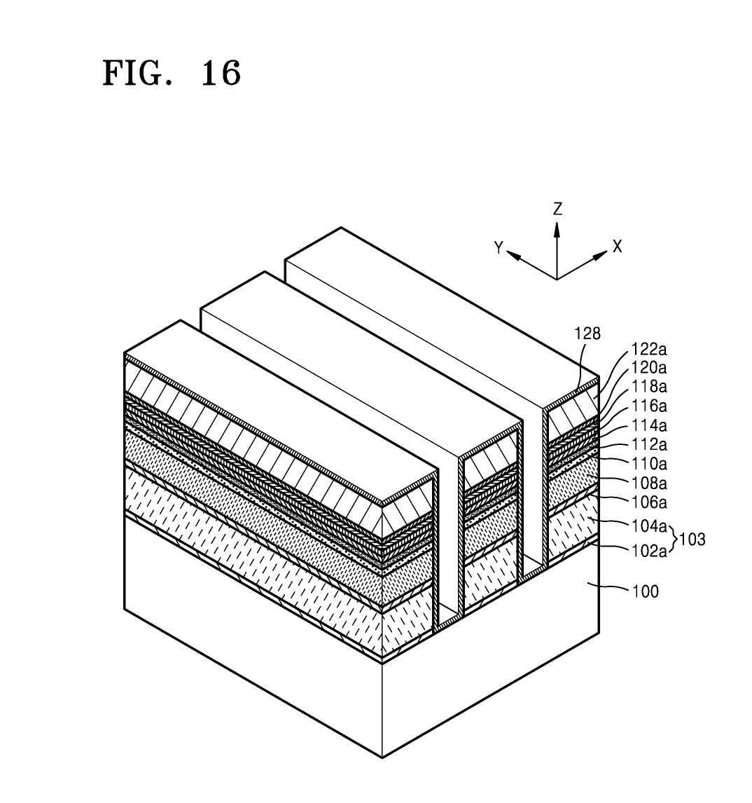

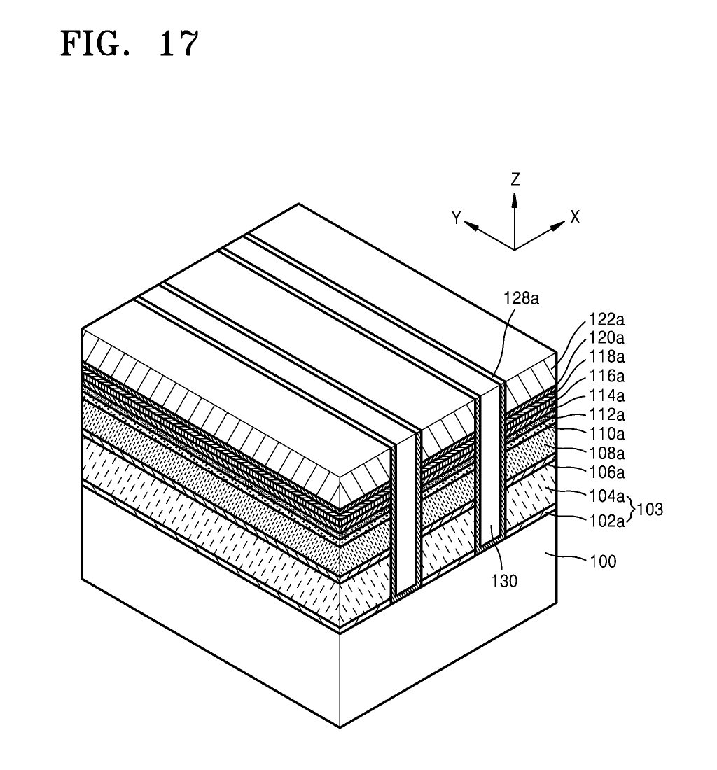

FIG. 10 is a cumulative distribution diagram showing a high resistance state and a low resistance state of a variable resistance memory device MC/R according to the inventive concept. FIG. 11 is a cumulative distribution diagram showing a high resistance state and a low resistance state of a comparative example of a variable resistance memory device.

More specifically, FIG. 10 is a cumulative distribution diagram showing a high resistance state and a low resistance state of the MC/R (30-5) of FIG. 9 manufactured on a wafer (substrate) and when a first cycle voltage is applied thereto. FIG. 11 is a cumulative distribution diagram showing a high resistance state and a low resistance state of a variable resistance memory device, similar to that of FIG. 9 but without the first and second buffer layers 43 and 53 and manufactured on a wafer (substrate), and when a first cycle voltage is applied.

A standard deviation of a cumulative distribution of the MC/R (30-5), as shown in FIG. 10, ranges from 0.22 to 0.24. A standard deviation of a cumulative distribution of the comparative example of the variable resistive memory device, as shown in FIG. 11, ranges from 0.76 to 1.20. In other words, the cumulative distribution of the MC/R (30-5) according to the inventive concept is less dispersed than that of the comparative example. Therefore, memory cells of the present embodiment have better properties than those of the comparative example.

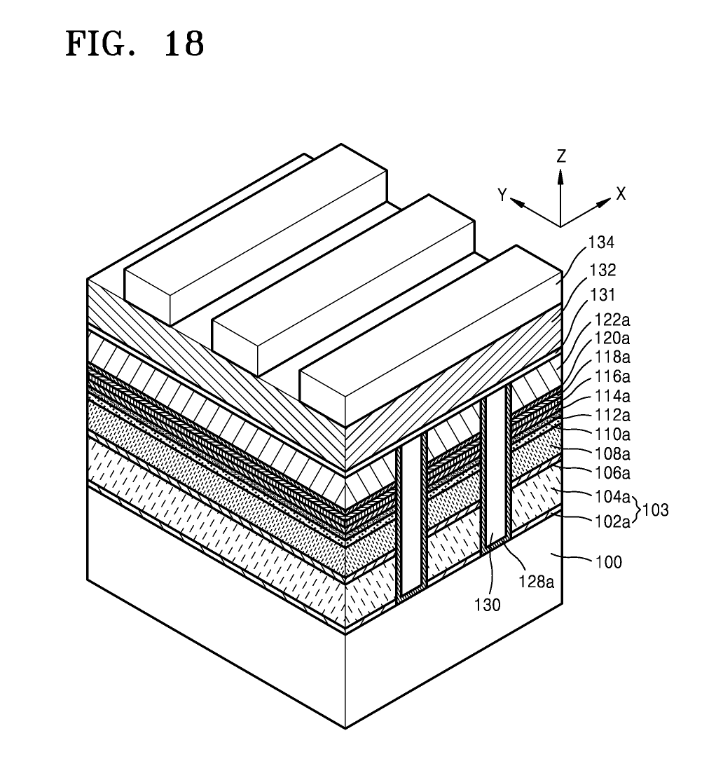

FIG. 12 is a table of an interface root mean square (RMS) of the embodiment of the variable resistive memory device according to the inventive concept and the comparative example, described above.

As illustrated in FIG. 12, an interface RMS between the first buffer layer 43 and the first barrier layer 45 and an interface RMS between the second barrier layer 51 and the second buffer layer 53 of the MC/R (30-5) are 4.94, and an interface RMS between the first electrode layer 41 and the first barrier layer 45 and an interface RMS between the second barrier layer 51 and the second electrode layer 49 of the comparative example are 7.96.

Therefore, the MC/R (30-5) according to the inventive concept exhibits improved interface morphology between the electrode layers (41 and 49) and the barrier layers (45 and 51) though the provision of the first and second buffer layers 43 and 53, and exhibits improved memory cell properties, as compared to a corresponding device without the barrier layers.

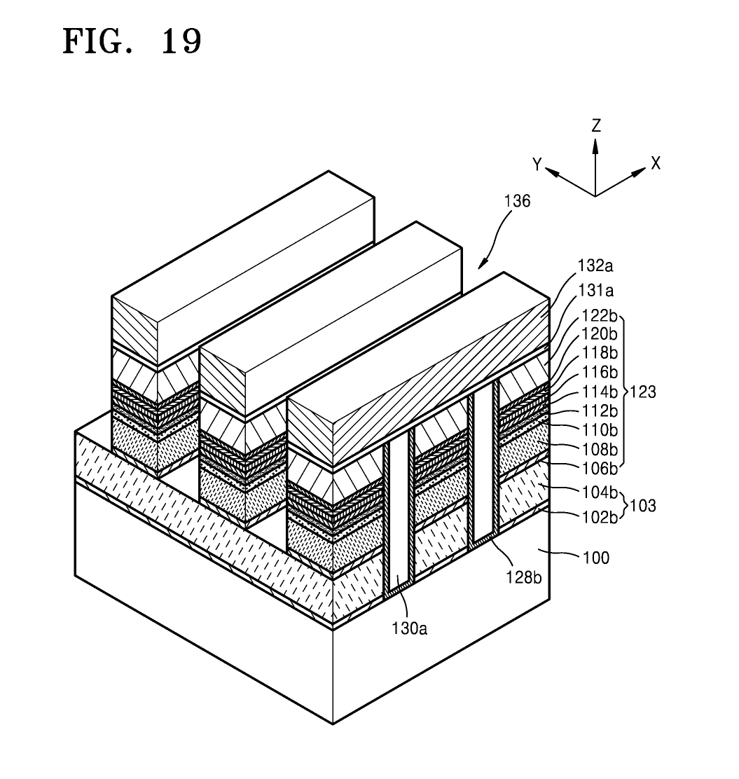

FIGS. 13 to 20 are perspective views illustrating an embodiment of a method of manufacturing a variable resistive memory device, according to the inventive concept.

Referring to FIG. 13, a first barrier metal layer 102 and a first metal layer 104 are formed on a substrate 100. The first barrier metal layer 102 may be formed of Ti, TiN, Ta, or TaN. The first metal layer 104 may be formed of Au, Ag, Cu, Al, TiA1N, W, WN, Ir, Pt, Pd, Ru, Zr, Rh, Ni, Co, Cr, Sn, Zn, or ITO, or an alloy of any such material.

A second barrier metal layer 106, a selection device layer 108, a third barrier metal layer 110, a first buffer material layer 112, a first barrier oxide layer 114, a variable resistance material layer 116, a second barrier oxide layer 118, a second buffer material layer 120, and a fourth barrier metal layer 122 are sequentially stacked on the first metal layer 104.

The first to third barrier metal layers 102, 106, and 110 may be formed of the same material. However, the second barrier metal layer 106 is optional, i.e., may be omitted. The selection device layer 108 may be formed of the same material as the selection device S of the device of FIG. 3. The first and second buffer material layers 112 and 120 may be respectively formed of the same material as the first and second buffer layers 43 and 53 of the devices of FIGS. 5 and 6. The first and second barrier oxide layers 114 and 118 may be respectively formed of the same material as the first and second barrier layers 45 and 51 of the devices of FIGS. 5 and 6. The variable resistance material layer 116 may be formed of the same material as the variable resistance layer 47 of the device of FIG. 5.

Referring to FIG. 14, a first hard mask pattern 124 is formed on the fourth barrier metal layer 122. The first hard mask pattern 124 may include an insulating material. The first hard mask pattern 124 may be a silicon oxide layer pattern. The first hard mask pattern 124 may be formed by of a stack of layers. For example, the first hard mask pattern 124 may be formed by forming a silicon oxide layer, a spin-on hard mask layer, and a silicon oxynitride layer one atop the other in the foregoing order.

The first hard mask pattern 124 may be formed by performing photolithography on a hard mask material layer. The first hard mask pattern 124 may be a line pattern whose linear segments each extend in a second direction, for example, the Y-axis direction in the figure.

Referring to FIG. 15, the layers under the first hard mask pattern 124 are sequentially etched using the first hard mask pattern 124 as an etch mask. That is, the fourth barrier metal layer 122, the second buffer material layer 120, the second barrier oxide layer 118, the variable resistance material layer 116, the first barrier oxide layer 114, the first buffer material layer 112, the third barrier metal layer 110, the selection device layer 108, the second barrier metal layer 106, the first metal layer 104, and the first barrier metal layer 102 are sequentially etched to be patterned based on the first hard mask pattern 124.

By performing the etching process, a fourth preliminary barrier metal layer pattern 122a , a second preliminary buffer layer pattern 120a , a second preliminary barrier oxide layer pattern 118a , a preliminary variable resistance layer pattern 116a , a first preliminary barrier oxide layer pattern 114a , a first preliminary buffer layer pattern 112a , a third preliminary barrier metal layer pattern 110a , a preliminary selection device layer pattern 108a , a second preliminary barrier metal layer pattern 106a , a first preliminary metal layer pattern 104a , and a first preliminary barrier metal layer pattern 102a are sequentially formed from the top of the structure down.

Also, by performing the etching process, a first trench 126 is formed between the above-mentioned preliminary patterns. A surface of the substrate 100 may be exposed through the first trench 126. The etching process may be an anisotropic etching process.

The first preliminary barrier metal layer pattern 102a and the first preliminary metal layer pattern 104a may serve as first signal lines (or first electrode lines) 103. The first signal lines 103 extend in the second direction, for example, the Y-axis direction. A portion of the first hard mask pattern 124 may be removed by the etching process. Then, the remaining portion of the first hard mask pattern 124 is removed.

Referring to FIG. 16, a first protection layer 128 is formed along the above-mentioned preliminary patterns and the substrate 100 at the bottom of the first trench 126. The first protection layer 128 may protect side walls of each of the above-described preliminary patterns. The first protection layer 128 may be formed of an insulating material. Examples of materials that may form the first protection layer 128 are silicon nitride and aluminum oxide.

Referring to FIG. 17, an insulating material layer is formed on the first protection layer 128 to fill the first trench 126. The insulating material layer is planarized and an insulating layer 130 is formed in the first trench 126. As a result, an upper surface of the fourth preliminary barrier metal layer pattern 122a may be exposed. A first preliminary protection layer pattern 128a may be formed along surfaces that delimit the sides and bottom of the first trench 126.

Referring to FIG. 18, a fifth barrier metal layer 131 and a second metal layer 132 are formed on the fourth preliminary barrier metal layer pattern 122a , the insulating layer 130, and the first preliminary protection layer pattern 128a . The fifth barrier metal layer 131 may be formed of the same material as the first barrier metal layer 102. The second metal layer 132 may be formed of the same material as the first metal layer 104.

A second hard mask pattern 134 is formed on the second metal layer 132. The second hard mask pattern 134 may be formed as a line pattern of linear segments each extending in a first direction that is perpendicular to the second direction, for example, the X-axis direction in the figure.

Referring to FIG. 19, the second metal layer 132, the fifth barrier metal layer 131, the fourth preliminary barrier metal layer pattern 122a , the second preliminary buffer layer pattern 120a , the second preliminary barrier oxide layer pattern 118a , the preliminary variable resistance layer pattern 116a , the first preliminary barrier oxide layer pattern 114a , the first preliminary buffer layer pattern 112a , the third preliminary barrier metal layer pattern 110a , the preliminary selection device layer pattern 108a , and the second preliminary barrier metal layer pattern 106a are sequentially etched using the second hard mask pattern 134 as an etch mask.

As a result, a second metal layer pattern 132a , a fifth barrier metal layer pattern 131a , a fourth barrier metal layer pattern 122b , a second buffer layer pattern 120b , a second barrier oxide layer pattern 118b , a variable resistance layer pattern 116b , a first barrier oxide layer pattern 114b , a first buffer layer pattern 112b , a third barrier metal layer pattern 110b , a selection device layer pattern 108b , and a second barrier metal layer pattern 106b are sequentially formed from the top of the structure down. Also, as a result, a second trench 136 is formed. During the etching process, the first preliminary protection layer pattern 128a is also etched and thus a first protection layer pattern 128b is formed, and the insulating layer 130 is also etched and thus an insulating pattern 130a is formed.

The second metal layer pattern 132a and the fifth barrier metal layer pattern 131a that are formed by the etching process may serve as second signal lines (or second electrode lines). Pillars 123 are also formed by the etching process. The pillars 123 may each include respective ones of the fourth barrier metal layer pattern 122b , the second buffer layer pattern 120b , the second barrier oxide layer pattern 118b , the variable resistance layer pattern 116b , the first barrier oxide layer pattern 114b , the first buffer layer pattern 112b , the third barrier metal layer pattern 110b , the selection device layer pattern 108b , and the second barrier metal layer pattern 106b . The pillars 123 thus comprise variable resistors. The third and fourth barrier metal layer patterns 110b and 122b may be a first electrode layer and a second electrode layer of the variable resistor, respectively. Then, the second hard mask pattern 134 is removed.

Referring to FIG. 20, a second protection layer 138 is formed along a bottom surface and side surface of i.e., conformally on, the structure constituted by the second metal layer pattern 132a , the fifth barrier metal layer pattern 131a , the fourth barrier metal layer pattern 122b , the second buffer layer pattern 120b , the second barrier oxide layer pattern 118b , the variable resistance layer pattern 116b , the first barrier oxide layer pattern 114b , the first buffer layer pattern 112b , the third barrier metal layer pattern 110b , the selection device layer pattern 108b , and the second barrier metal layer pattern 106b.

That is, the second protection layer 138 is formed along the second trench 136 but does not fill the second trench 136. The second protection layer 138 prevents a side surface of the variable resistance layer pattern 116b from being exposed. The second protection layer 138 may be formed of an insulating material. Examples of materials that may be used to form the second protection layer 138 include silicon nitride and aluminum oxide. The first and second protection layers 128 and 139 may be formed of the same material or different materials.

As a result of the processes described above, an insulating unit (or simply, an insulator) that includes the insulating pattern 130a or protection layers (128b and 138) exists between the pillars 123, between the first signal lines (or first electrode lines) 103, and between second signal lines or second electrode lines 132a . Also, the device takes on different appearances depending on the direction in section, A or B along which it is viewed, owing to the first signal lines 103, the protection layers (128b and 138), and the insulating pattern 130a.

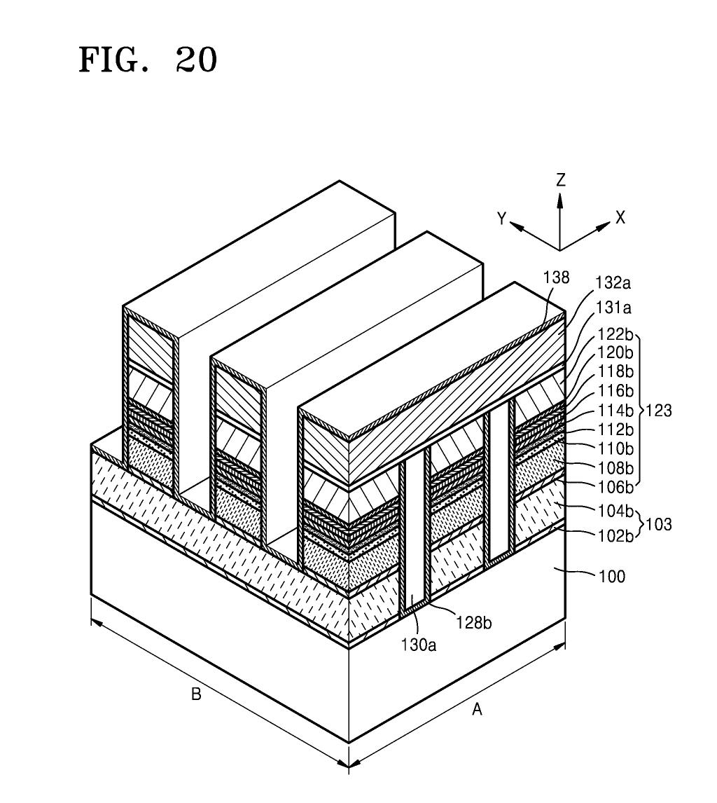

FIGS. 21 and 22 are circuit diagrams of a memory cell array of embodiments of variable resistive memory devices, according to the inventive concept.

Specifically, FIG. 21 illustrates a memory cell array 200-2a in which a memory cell only includes the variable resistors R of FIGS. 5 to 9. FIG. 22 illustrates a memory cell array 200-2b in which a memory cell includes variable resistors R (of any type described with reference to FIGS. 5 to 9) and a diode D as a selection device (as described with reference to FIGS. 1 to 3). Hereinafter, FIG. 22 will be mainly described.

The memory cell arrays 200-2a and 200-2b of FIGS. 21 and 22 may be horizontal arrays. The memory cell arrays 200-2a and 200-2b may each have a plurality of word lines WL1 to WLn, a plurality of bit lines BL1 to BLm, and a plurality of memory cells MC. The number of word lines WL1 to WLn, the number of bit lines BL1 to BLm, and the number of memory cells MC may vary according to requirements.

In the embodiment of FIG. 22, the selection device is indicated with reference character “D” because the selection device is a diode. The variable resistor R may be referred to as variable resistance material and the selection device D may be referred to as a switching device.

Each variable resistor R is interposed between and connected to a selection device D and one of the bit lines BL1 to BLm, and the selection device D is interposed between and connected to the variable resistor R and one of the word lines WL1 to WLn. Alternatively, the selection device D may be interposed between and connected to one of the plurality of bit lines BL1 to BLm and the variable resistor R, and the variable resistor R may be interposed between and connected to the selection device D and one of the plurality of word lines WL1 to WLn.

In the present embodiment, the variable resistor R may be switched between one of a plurality of resistance states by applying an electric pulse thereto. For example, the variable resistor R may include a phase-change material that assumes different states of crystallization (e.g., between fully crystallized and amorphous) depending on the amount of current supplied. The phase-change material may be a compound consisting of two elements, for example, GaSb, InSb, InSe. Sb₂Te₃, GeTe, a compound consisting of three elements, for example, GeSbTe, GaSeTe, InSbTe, SnSb₂Te₄, InSbGe, a compound consisting of four elements, for example, AgInSbTe, (GeSn)SbTe, GeSb(SeTe), Te₈₁Ge₁₅Sb₂S₂, or other various phase change materials.

The phase-change material may assume an amorphous state having a relatively high resistance or a crystal state having a relatively low resistance. A voltage applied to a word line or a bit line that is connected to the selection device D may generate the current supplied to the variable resistor R. The phase-change material may change phases according to Joule's heat generated by the current. Also, data may be input of the phase change.

According to another embodiment, instead of the phase-change material, the variable resistor R may include perovskite compounds, a transition metal oxide layer, magnetic materials, ferromagnetic materials, or antiferromagnetic materials.

In other examples of this embodiment, the selection device D is a PN junction diode or a PIN junction diode. An anode of the diode may be connected to the variable resistor R, and a cathode of the diode may be connected to one of the plurality of word lines WL1 to WLn. If a voltage difference between the anode and the cathode of the diode is greater than a threshold voltage of the diode, the diode is turned on and current may be supplied to the variable resistor R.

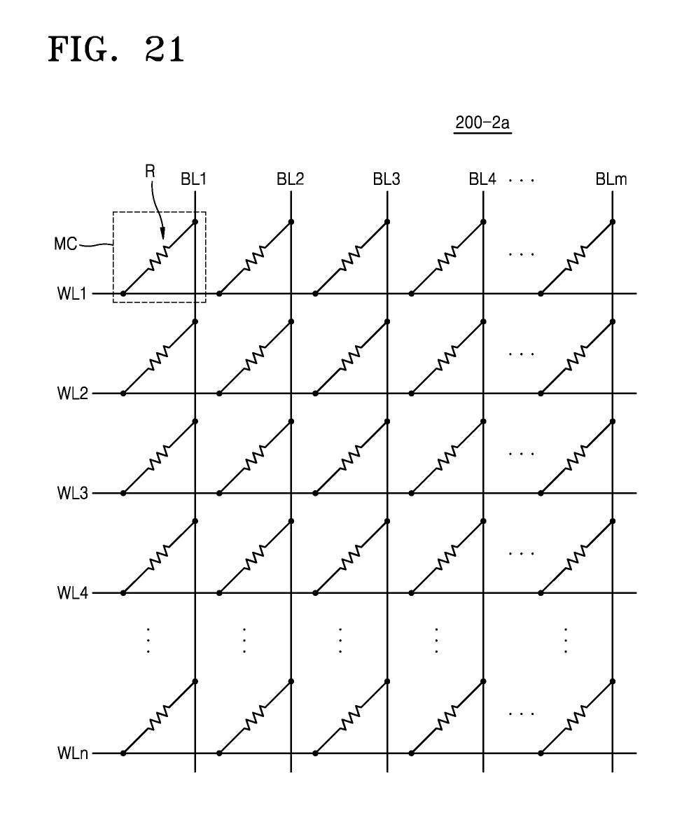

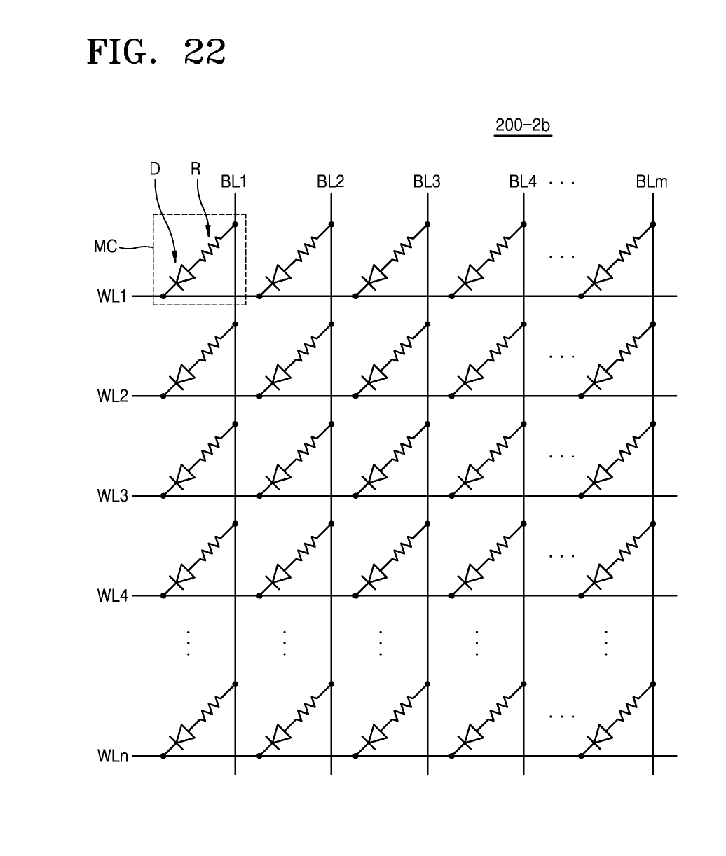

FIG. 23 is a perspective view of a memory cell array 200-3 according to an embodiment of the inventive concept. FIG. 24 is a circuit diagram of a unit memory cell of FIG. 23.

The memory cell array 200-3 may include a plurality of bit lines BL, a plurality of word lines WL, and a plurality of memory cells. The plurality of bit lines BL may cross the plurality of word lines WL. The memory cells may be disposed at locations where the bit lines BL and the word lines WL cross and may each include a diode D, as a selection device, and a variable resistor R9 of any of the types shown in and described with reference to FIGS. 5 to 9). The memory cell array 200-3 may have a 3-dimensional vertical structure including a stack of several horizontal arrays of the memory cells. The memory cells may have identical structures. In this example, the memory cell array 200-3 includes a lower horizontal array of word lines WL, a two-dimensional horizontal lower array of memory cells on the lower horizontal array of word lines WL, a horizontal array of bit lines BL, a two-dimensional horizontal upper array of memory cells on the horizontal array of bit lines BL, and an upper horizontal array of word lines WL on the two-dimensional horizontal upper array of memory cells.

FIGS. 23 and 24 illustrate an example in which a memory cell array of a resistive memory device according to the inventive concept is a crossbar array. In the crossbar array, variable resistors R1 and R2 (of the horizontal arrays of memory cells, respectively) are symmetrical about a bit line BLn, but a resistive memory device comprising a crossbar array need not have such symmetry. In an case, in this example, variable resistor R1 is interposed between and electrically connected to the bit line BLn and a word line WLm+1 the horizontal upper array of word lines, and variable resistor R1 is interposed between and electrically connected to the bit line BLn and a word line WLm of the horizontal lower array of word lines.

That is, in this case, the variable resistors R1 and R2 may be manufactured such that the electrode above the variable resistor R2 and the electrode below the variable resistor R1 are the same (i.e., a single common electrode.

Furthermore, although in the example shown in FIG. 24 each unit memory cell has only a variable resistor R1 or R2, the inventive concept is not so limited. Rather, each memory cell may include a selection device and the variable resistors R1 and R2 in series.

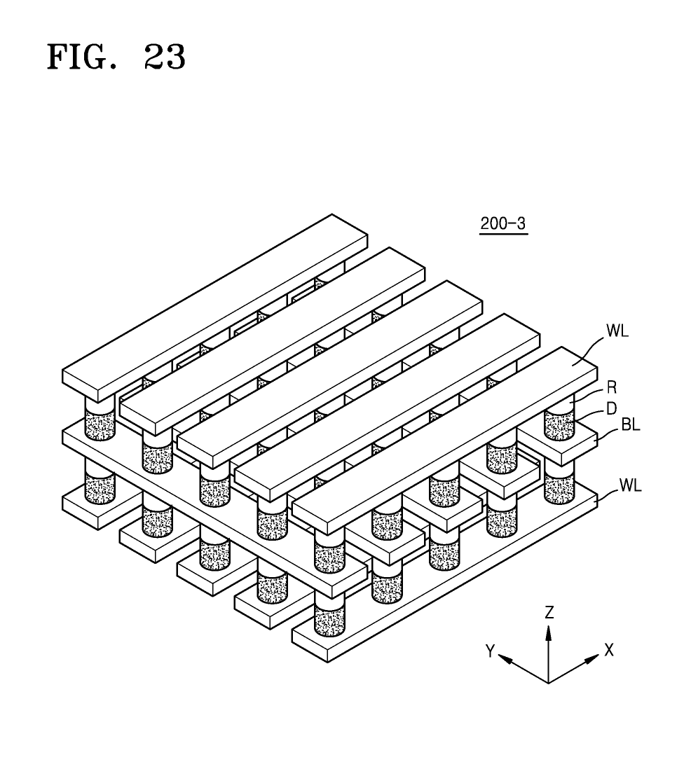

FIG. 25 is a block diagram of an embodiment of a variable resistive memory device 300 according to the inventive concept.

The variable resistive memory device 300 includes a memory cell array 310, a decoder 320, a read/write circuit 330, an input/output (I/O) buffer 430, and a controller 350. The memory cell array 310 may be similar to any of those described with reference to FIGS. 1 to 9 and FIGS. 13 to 20, and thus, a detailed description of the memory cell array 310 will be omitted.

Memory cells of the memory cell array 310 may be connected to the decoder 320 via a word line array WL/ and to the read/write circuit 330 via a bit line array BL/. The decoder 320 receives an external address ADD. The decoder 320 is controlled by the controller 350 that operates according to a control signal CTRL and thus decodes a row address and a column address to be accessed in the memory cell array 350.

The read/write circuit 330 receives data DATA from the I/O buffer 340 and a data line array DL/ and is controlled by the controller 350 and thus records data in a selected memory cell of the memory cell array 310 or transfers data read from a selected memory cell of the memory cell array 310 to the I/O buffer 340.

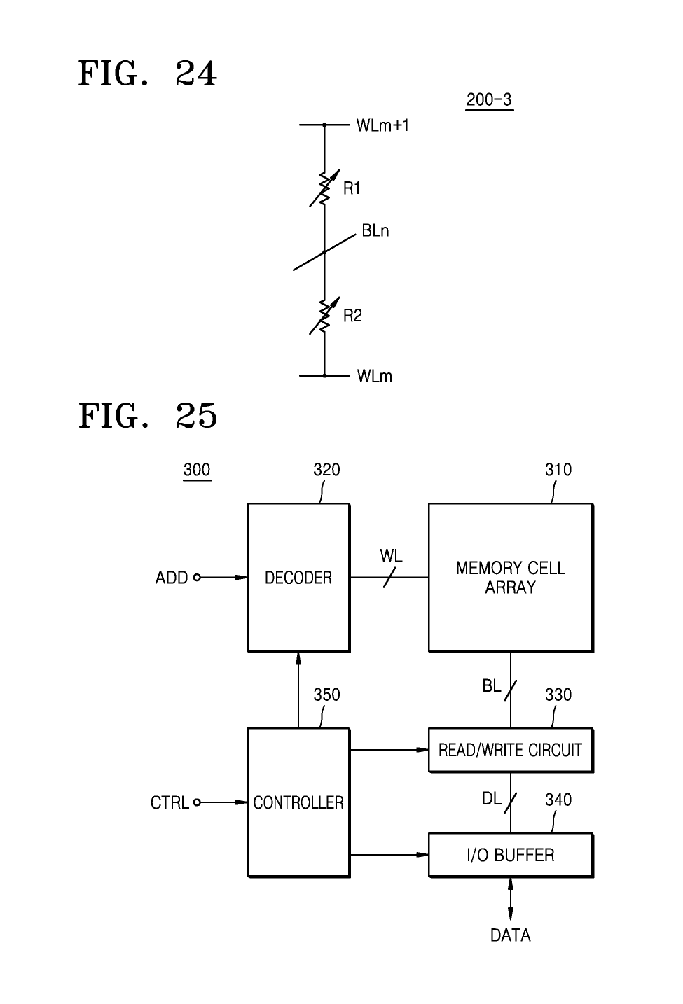

FIG. 26 is a block diagram of an embodiment of a data processing system 400 according to the inventive concept.

The data processing system 400 includes a host, a variable resistive memory device 410, and a memory controller 420 that is connected to the host and the variable resistive memory device 410. The memory controller 420 may access the variable resistive memory device 410 in response to requests from the host. The memory controller 420 may include a processor 4201, an operation memory 4203, a host interface 4205, and a memory interface 4207.

The processor 4201 controls operations of the memory controller 420, and the operation memory 4203 may store applications, data, and control signals that are necessary for the operations of the memory controller 420. The host interface 4205 performs protocol conversion for the host and the memory controller 420 to exchange the data/control signals. The memory interface 4207 performs protocol conversion for the memory controller 420 and the variable resistive memory device 410 to exchange the data/control signals. The variable resistive memory device 410 is similar to the variable resistive memory device 300 of FIG. 25 and thus, will not be described here in detail. The data processing system 400 may be realized as a memory card but is not limited thereto.

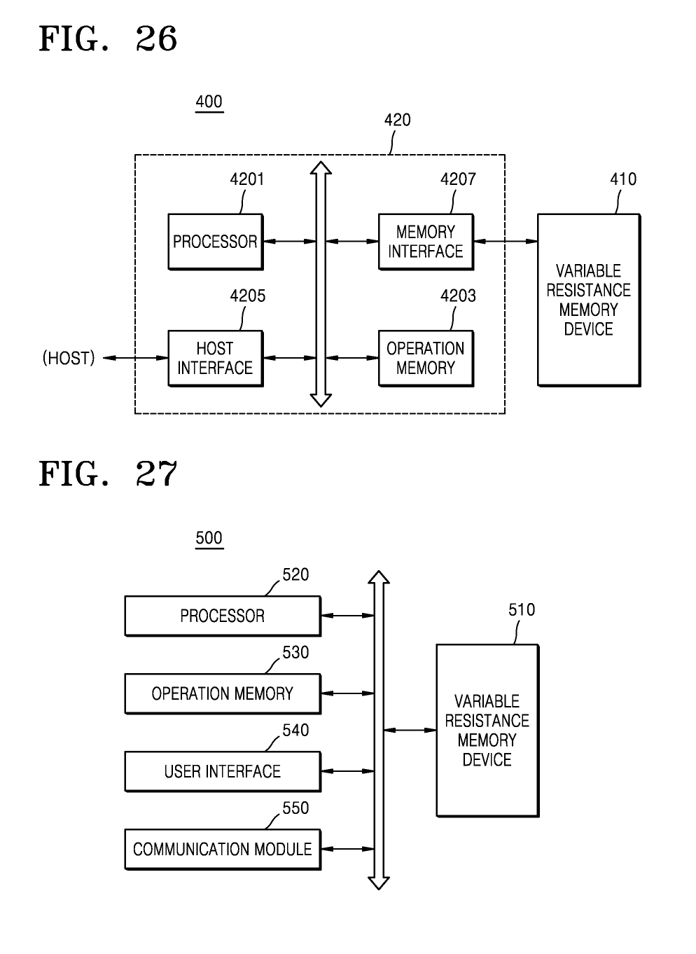

FIG. 27 is a block diagram of an embodiment of a data processing system 500 according to the inventive concept.

The data processing system 500 includes a variable resistive memory device 510, a processor 520, an operation memory 530, and a user interface 540. If necessary, a communication module 550 may be further included. The processor 520 may be a central processing unit.

The operation memory 530 may store applications, data, and control signals that are necessary for operations of the data processing system 500. The user interface 540 provides an environment in which a user may access the data processing system 500, data process operations and results of the data processing system 500. The variable resistive memory device 510 is similar to the variable resistive memory device 300 of FIG. 25 and thus, will not be described here in detail.

The data processing systems 400 and 500 of FIGS. 26 and 27 may be used as a drive, an embedded or external memory card of a portable electronic device, or an application chipset of an image processor and others.

As described above, a variable resistive memory device according to the inventive concept includes a barrier layer disposed between a variable resistance layer and one of a first electrode layer and a second electrode layer, and a buffer layer disposed between the barrier layer and one of the first electrode layer and the second electrode layer. The buffer layer may be a reaction prevention layer that prevents an interaction between the first and second electrode layers and the barrier layer. The buffer layer may be an interface improvement layer that improves the interface morphology between the first and second electrode layers and the barrier layer. Embodiments of the variable resistive memory device according to the inventive concept may have improved memory cell properties due to the buffer layer.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A variable resistance memory device comprising:
a first electrode;
a variable resistance layer disposed on the first electrode;
a second electrode disposed on the variable resistance;
a barrier layer disposed between the variable resistance layer and one of the first and second electrodes; and
a buffer layer disposed between the barrier layer and one of the first and second electrodes.

2. The variable resistance memory device of claim 1, wherein the variable resistance layer is a layer of material whose resistance can be changed by varying an electric field in which the layer of material is disposed.

3. The variable resistance memory device of claim 1, wherein the barrier layer is an oxide layer.

4. The variable resistance memory device of claim 3, wherein the buffer layer is at least one layer selected from the group consisting of a metal oxide layer and a metal nitride layer.

5. The variable resistance memory device of claim 1, wherein the buffer layer is an interface improvement layer that improves the interface morphology between the barrier layer and said one of the first and second electrode layers.

6. The variable resistance memory device of claim 1, further comprising a selection device layer disposed under the variable resistance layer.

7. A variable resistance memory device comprising:
a first electrode;
a first barrier layer disposed on the first electrode;
a variable resistance layer disposed on the first barrier layer;
a second electrode disposed on the variable resistance layer; and
a first reaction prevention layer disposed on the first electrode and which prevents an interaction between the first electrode and the first barrier layer.

8. The variable resistance memory device of claim 7, wherein the first barrier layer is an oxide layer, and wherein the first reaction prevention layer is at least one layer selected from the group consisting of a metal oxide layer and a metal nitride layer.

9. The variable resistance memory device of claim 7, further comprising a second barrier layer disposed on the variable resistance layer and a second reaction prevention disposed on the second barrier layer and which prevents an interaction between the second electrode layer and the second barrier layer.

10. The variable resistance memory device of claim 9, wherein the second barrier layer is an oxide layer, and wherein the second reaction prevention layer is at least one layer selected from the group consisting of a metal oxide layer and a metal nitride layer.

11. The variable resistance memory device of claim 7, further comprising a selection device layer disposed under the first electrode.

12. The variable resistance memory device of claim 7, wherein a first buffer layer is disposed on the first electrode, the first barrier layer is disposed on the first buffer layer, a second barrier layer is disposed on the variable resistance layer, a second buffer layer is disposed on the second barrier layer, and the second electrode is disposed on the second buffer layer.

13. The variable resistance memory device of claim 12, wherein the first and second barrier layers are oxide layers.

14. The variable resistance memory device of claim 13, wherein each of the first and second buffer layers is at least one layer selected from the group consisting of a metal oxide layer and a metal nitride layer.

15. The variable resistance memory device of claim 12, wherein the first buffer layer is a first interface improvement layer that improves the interface morphology between the first barrier layer and the first electrode, and the second buffer layer is a second interface improvement layer that improves the interface morphology between the second barrier layer and the second electrode.

16. The variable resistance memory device of claim 12, wherein the first buffer layer is a first reaction prevention layer that prevents an interaction between the first barrier layer and the first electrode, and the second buffer layer is a second reaction prevention layer that prevents an interaction between the second barrier layer and the second electrode layer.

17. The variable resistance memory device of claim 12, further comprising a selection device layer disposed under the variable resistance layer.

18-28. (canceled)

29. A variable resistance memory device comprising:
a first horizontal array of electrodes;
a second horizontal array of electrodes spaced vertically from the first horizontal array; and
an array of memory cells interposed between the first and second horizontal arrays of electrodes, each of the memory cells electrically connected to a respective one of the electrodes of the first horizontal array and a respective one of the electrodes of the second horizontal array, and
wherein each of the memory cells has the form of a pillar interposed between the respective ones of the electrodes of the first and second horizontal arrays, and
each of the pillars comprises:
a variable resistor comprising a layer of material that can assume a first state in which the resistance of the variable resistor has a first value and another state in which the resistance of the variable resistor has a second value different from the first value,
an oxide layer interposed, as a barrier, between the variable resistor and the respective electrode of one of the first and second horizontal arrays, and
at least one of a metal oxide layer and a metal nitride layer interposed, as a buffer, between the barrier layer and said respective electrode, and
wherein the layer constituting said variable resistor, the oxide layer constituting the barrier, and each said at least one layer constituting the buffer have different compositions from one another.

30-34. (canceled)

35. The variable resistance memory device of claim 29, comprising an array of first conductive lines, and an array of second conductive lines, each of the first conductive lines extending longitudinally in a first horizontal direction and constituting a respective row of the first electrodes, and each of the second conductive extending longitudinally in a second horizontal direction and constituting a respective column of the second electrodes.

36. The variable resistance memory device of claim 29, wherein each of the pillars also includes an oxide layer interposed between the variable resistor and the respective electrode of the other of the first and second horizontal arrays, and constituting a second barrier of the pillar,
at least one of a metal oxide layer and a metal nitride layer interposed between the second barrier and said respective electrode of the other of the first and second horizontal arrays, and constituting a second buffer of the pillar.
